(19) United States
(12) Patent Application Publication
(10) Pub. No.: US 2023/0203662 A1
(43) Pub. Date: Jun. 29, 2023

(54) FILM FORMATION APPARATUS AND METHOD OF USING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); National University Corporation Kyoto Institute of Technology, Kyoto-shi (JP)

(72) Inventors: TATSUJI NAGAOKA, Nisshin-shi (JP); HIROYUKI NISHINAKA, Kyoto-shi (JP); MASAHIRO YOSHIMOTO, Kyoto-shi (JP)

(21) Appl. No.: 18/065,740

(22) Filed: Dec. 14, 2022

(30) Foreign Application Priority Data
Dec. 27, 2021 (JP) 2021-213031

(51) Int. Cl. C23C 16/54; C23C 16/52; C23C 16/44; C23C 16/448; C23C 16/48

(52) U.S. Cl. CPC C23C 16/54; C23C 16/52; C23C 16/4412; C23C 16/4481; C23C 16/4486; C23C 16/481

(57) ABSTRACT

A film formation apparatus includes a stage for having a substrate thereon; a mist generation source that generates a mist of a solution containing at least water and in which a material for forming a film on the substrate is dissolved; a supply path that conveys the mist toward the substrate on the stage by a flow of a carrier gas; and a heater that heats at least a part of the supply path. The part of the supply path heated by the heater is provided as a mist heating section in which infrared rays are radiated from an inner surface of the supply path toward the mist. The inner surface of the supply path in the mist heating section is coated with a coating layer containing at least one of an oxide and a hydroxide of an element present in the mist.

### CROSS REFERENCE TO RELATED APPLICATION

The present application claims the benefit of priority from Japanese Patent Application No. 2021-213031 filed on Dec. 27, 2021. The entire disclosures of the above application are incorporated herein by reference.

### TECHNICAL FIELD

The present disclosure relates to a film formation apparatus and a method of using the same.

### BACKGROUND

There is known a film formation apparatus configured to form a film on the surface of a substrate by a mist chemical vapor deposition (CVD) method. The film formation apparatus includes a supply path through which mist generated by a mist generation source is conveyed by a flow of carrier gas and a heater that heats at least a section of the supply path.

In a manufacturing method using such a film formation apparatus, heating of the supply path may suppress the mist from condensing and aggregating in the supply path. Since the condensation and aggregation of the mist are suppressed, the amount of mist supplied to the substrate may be increased, and the speed of forming the film may be improved.

### SUMMARY

The present disclosure describes a film formation apparatus for forming a film on a surface of a substrate and a method of using the film formation apparatus. The film formation apparatus according to an aspect includes a stage for having the substrate thereon; a mist generation source that generates mist of a solution containing at least water and in which a material for forming the film is dissolved; a supply path that conveys the mist generated by the mist generation source toward the substrate on the stage by a flow of a carrier gas; and a heater that heats at least a part of the supply path. The part of the supply path heated by the heater is provided as a mist heating section in which infrared rays are radiated from an inner surface of the supply path toward the mist. The inner surface of the supply path in the mist heating section is coated with a coating layer containing at least one of an oxide and a hydroxide of an element present in the mist. A method of using the film formation apparatus according to an aspect includes: forming a coating layer on the inner surface of the supply path in the mist heating section by supplying the mist generated by the mist generation source to the mist heating section while operating the heater; and after the forming of the coating layer, forming the film on the surface of the substrate by supplying the mist generated by the mist generation source to the substrate on the stage through the supply path while operating the heater.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a diagram schematically showing a configuration of a film formation apparatus according to a first embodiment;

FIG. 2 is a diagram showing an enlarged sectional view of a part II in FIG. 1;

FIG. 3 is a diagram for explaining a method of using the film formation apparatus according to the first embodiment, and particularly showing a state of a preliminary process;

FIG. 4 is a diagram for explaining a method of using the film formation apparatus according to the first embodiment, and particularly showing a state of a film forming process;

FIG. 5 is a diagram schematically showing a configuration of a film formation apparatus according to a second embodiment;

FIG. 6 is a diagram showing an enlarged sectional view of a part VI in FIG. 5;

FIG. 7 is a diagram for explaining a method of using the film formation apparatus according to the second embodiment, and particularly showing a state of a preliminary process;

FIG. 8 is a diagram schematically showing a configuration of a film formation apparatus according to a third embodiment;

FIG. 9 is a diagram showing an enlarged sectional view of a part IX in FIG. 8;

FIG. 10 is a diagram for explaining a method of using the film formation apparatus according to the third embodiment, and particularly showing a state of a preliminary process;

FIG. 11 is a diagram schematically showing a configuration of a film formation apparatus according to a fourth embodiment;

FIG. 12 is a diagram showing an enlarged sectional view of a part XII in FIG. 11; and

FIG. 13 is a diagram for explaining a method of using the film formation apparatus according to the fourth embodiment, and particularly showing a state of a preliminary process.

### DETAILED DESCRIPTION

In a film formation apparatus for forming a film on the surface of a substrate by a mist chemical vapor deposition (CVD) method, a supply path through which mist generated by a mist generation source conveyed by a flow of carrier gas may be heated at least at a part by a heater. The heating of the supply path may suppress the mist from condensing and aggregating in the supply path. If the condensation and aggregation of the mist are suppressed, the amount of mist supplied to the substrate may be increased, and the speed of forming the film may be improved.

However, even if the supply path is heated, it is difficult to completely suppress the condensation and aggregation of the mist in the supply path. As a result, when the film formation apparatus is used repeatedly, deposits resulting from the condensation and aggregation of the mist adhere to the inner surface of the supply path. Further, it was found that progress of the adhesion of the deposits caused deterioration of the quality of a film (hereinafter, referred to as the film quality) formed on the substrate. The present disclosure provides a technique capable of suppressing such deterioration of the film quality.

When the supply path is heated, the mist conveyed in the supply path is also heated, and the heated mist is supplied to the substrate. However, when the film formation apparatus is repeatedly used and the deposits adhered to the inner surface of the supply path progresses, the amount of heat (particularly, the dose of infrared rays) transmitted from the inner surface of the supply path to the mist decreases. As a result, the rise in temperature of the mist is reduced, and the temperature of the mist supplied to the substrate is lowered unintentionally, resulting in the deterioration of the film quality. Therefore, if the decrease in the amount of heat (particularly, the dose of infrared rays) transmitted from the inner surface of the supply path to the mist is suppressed in the course of repeated use of the film formation apparatus, the deterioration of the film quality can be suppressed. In order to suppress the deterioration of the film quality, it is conceivable to pre-coat the inner surface of the supply path with a material that corresponds to or approximates to the deposits derived from the mist.

According to an aspect of the present disclosure, it is disclosed a film formation apparatus for forming a film on a surface of a substrate. The film formation apparatus according to the aspect includes: a stage for having the substrate thereon, a mist generation source, a supply path, and a heater. The mist generation source is configured to generate mist of a solution containing at least water and in which a material for forming the film is dissolved. The supply path is configured to convey the mist generated by the mist generation source toward the substrate on the stage by means of a flow of a carrier gas. The heater is configured to heat at least a part of the supply path. The part of the supply path heated by the heater serves as a mist heating section in which infrared rays are radiated from an inner surface of the supply path toward the mist. The inner surface of the supply path in the mist heating section is coated with a coating layer, and the coating layer contains at least one of an oxide or a hydroxide of an element present in the mist.

In the film formation apparatus described above, the supply path includes the mist heating section as the part of the supply path heated by the heater. In the mist heating section, the infrared rays are radiated from the inner surface of the supply path toward the mist. The inner surface of the mist heating section is pre-coated with a material that corresponds to or approximates to deposits derived from the mist. As a result, even if deposits derived from the mist further adhere to the inner surface of the supply path in the course of repeated use of the film formation apparatus, the magnitude of decrease in the amount of heat (particularly, the amount of infrared rays) transmitted from the inner surface of the supply path to the mist will be reduced. As a result, the decrease in temperature of the mist supplied to the substrate is also suppressed. Accordingly, the film formation apparatus can continue the formation of films under predetermined optimal conditions over a long period of time.

In an embodiment of the present disclosure, the coating layer may be composed only of the element contained in the mist. According to such a configuration, it is possible to avoid inclusion of impurities in the film formed by the film formation apparatus.

In an embodiment of the present disclosure, the supply path may include a film formation chamber, and the stage may be arranged in the film formation chamber. In such a configuration, the temperature of the substrate when the film is formed is referred to as T1, and the temperature of the inner surface of the film formation chamber facing the surface of the substrate when the film is formed is referred to as T2. The temperature T1 may be higher than the temperature T2 (i.e., T1>T2). That is, it is configured as a so-called cold wall method. In the cold wall method, the mist is not heated in the film formation chamber. Therefore, the temperature rise of the mist in the mist heating section largely affects the final temperature of the mist supplied to the substrate, and thus also largely affects the film quality. In other words, in the cold wall method, the film quality can be effectively stabilized by stabilizing the temperature rise of the mist in the mist heating section. Thus, such a technique can be effectively employed.

In an embodiment of the present disclosure, the coating layer formed in the mist heating section may have an absorptivity of 50% or more of the infrared rays radiated toward the mist from the inner surface of the supply path. According to such a configuration, even when deposits derived from the mist further adhere in the course of repeated use of the film formation apparatus, the magnitude of decrease in the amount of infrared rays radiated to the mist is effectively suppressed.

In an embodiment of the present disclosure, the film formed on the surface of the substrate may be an epitaxial film. As another embodiment, the film formed on the surface of the substrate may not be an epitaxial film, but may be a film having a crystal structure or a film having no crystal structure.

In an embodiment of the present disclosure, the inner surface of the supply path in the mist heating section may be made of quartz. In this case, the quartz may contain a hydroxyl group (OH group). Quartz is a chemically stable substance and has excellent heat resistance. Therefore, the quartz can be used as the material forming the inner surface of the supply path. On the other hand, since quartz has a high transmittance in the infrared region, which is easily absorbed by water, the amount of infrared rays radiated to the mist will change largely when deposits due to the condensation and aggregation of the mist adhere thereto. In order to suppress such a change, it is preferable to form the coating layer on the inner surface of the supply path in advance. In this respect, the effect of the present technique is significantly exhibited.

In an embodiment of the present disclosure, the temperature of the heater is referred to as T3. The temperature T3 of the heater may be 100 degrees Celsius (° C.) or higher (i.e., T3≥100° C.). In order to suppress the mist of the solution containing water from condensing and aggregating, the temperature of the heater may be set to 100° C. or higher. However, if the temperature of the heater is set to 100° C. or higher, deposits tend to adhere to the inner surface of the supply path due to the evaporation of the water contained in the mist, resulting in a change in the amount of infrared rays radiated to the mist. In order to suppress such a change, it is preferable to form the coating layer on the inner surface of the supply path in advance. In this respect, the effect of the present technique is significantly exhibited.

In an embodiment of the present disclosure, the supply path may include a film formation chamber, and the stage may be arranged in the film formation chamber. In this case, the temperature of an inner surface of the film formation chamber is referred to as T2, and the temperature of the heater is referred to as T3. The temperature T2 may be lower than the temperature T3 (i.e., T2<T3). According to such a configuration, the mist will not be heated so much in the film formation chamber. Therefore, the temperature rise of the mist in the mist heating section largely affects the final temperature of the mist supplied to the substrate, and can also largely affect the film quality. In other words, when the temperature relationship T2<T3 described above is satisfied, the film quality can be effectively stabilized by stabilizing the temperature rise of the mist in the mist heating section. Thus, the present technique can be suitably employed.

In an embodiment of the present disclosure, the infrared rays radiated to the mist may have a wavelength λ of 7.8 micrometers or less (i.e., λ≤7.8). In the film formation using the mist of the solution containing water, a film is formed on the surface of the substrate since at least part of the water is removed. For this reason, the heater should normally have the temperature of 100° C. or higher, and such a heater radiates a large amount of infrared rays having the wavelength of 7.8 μm or less based on Wien's displacement law. The wavelength of 7.8 micrometers or less is in a wavelength band that is easily absorbed by water, and largely affects the temperature rise of mist containing water. Therefore, in order to stabilize the film quality, it is particularly effective to suppress changes in the amount of infrared rays radiated to the mist. For this reason, the present technique can be preferably employed.

The present technology is also embodied in a method of using a film formation apparatus. Such a film formation apparatus may include a stage for having a substrate thereon, a stage for heating the substrate on the stage, a mist generation source configured to generate a mist of a solution that contains at least water and in which a material for forming a film on the substrate is dissolved, a supply path configured to convey the mist generated by the mist generation source toward the substrate on the stage by means of a flow of a carrier gas, and a heater configured to heat at least a part of the supply path. In such a film formation apparatus, the part of the supply path heated by the path heater serves as a mist heating section in which infrared rays are radiated from an inner surface of the supply path to the mist.

According to an aspect of the present disclosure, a method of using the film formation apparatus includes a preliminary process and a film forming process performed after the preliminary process. The preliminary process includes forming a coating layer on the inner surface of the supply path in the mist heating section by supplying the mist generated by the mist generation source to the mist heating section, while operating the heater. The film forming process includes forming the film on the surface of the substrate by supplying the mist generated by the mist generation source to the substrate on the stage through the supply path, while operating the heater.

In the method of use described above, the inner surface of the mist heating section can be previously coated with a material that corresponds to or approximates to the deposits derived from the mist by performing the preliminary process. As such, it is possible to effectively suppress a decrease in the amount of heat (particularly, the amount of infrared rays) transmitted from the inner surface of the supply path to the mist in the film forming process performed after the preliminary process. As a result, the temperature of the mist supplied to the substrate does not drop unintentionally, and film formation can be continued over a long period of time under optimum predetermined conditions.

In an embodiment of the present disclosure, the temperature of the inner surface of the mist heating section in the preliminary process is referred to as T4, and the temperature of the heater in the film forming process is referred to as T3. The temperature T3 is lower than the temperature T4 (i.e., T3<T4). According to such a configuration, in the preliminary process, the temperature of the inner surface of the mist heating section is relatively high. Therefore, the formation of the coating layer is effectively promoted.

In an embodiment of the present disclosure, the temperature of the inner surface of the mist heating section in the preliminary process is referred to as T4, and the temperature of the substrate in the film forming process is referred to as T1. The temperature T1 is lower than the temperature T4 (i.e., T1<T4). According to such a configuration, in the preliminary process, the temperature of the inner surface of the mist heating section is relatively high. Therefore, the formation of the coating layer is effectively promoted.

In an embodiment of the present technology, the mist in the preliminary process may be the same as the mist in the film forming process. In this case, although not particularly limited, the preliminary process and the film forming process may be performed continuously. However, as another embodiment, the mist in the preliminary process may be different from the mist in the film forming process.

Hereinafter, specific embodiments of the present disclosure will be described in detail with reference to the drawings.

### First Embodiment

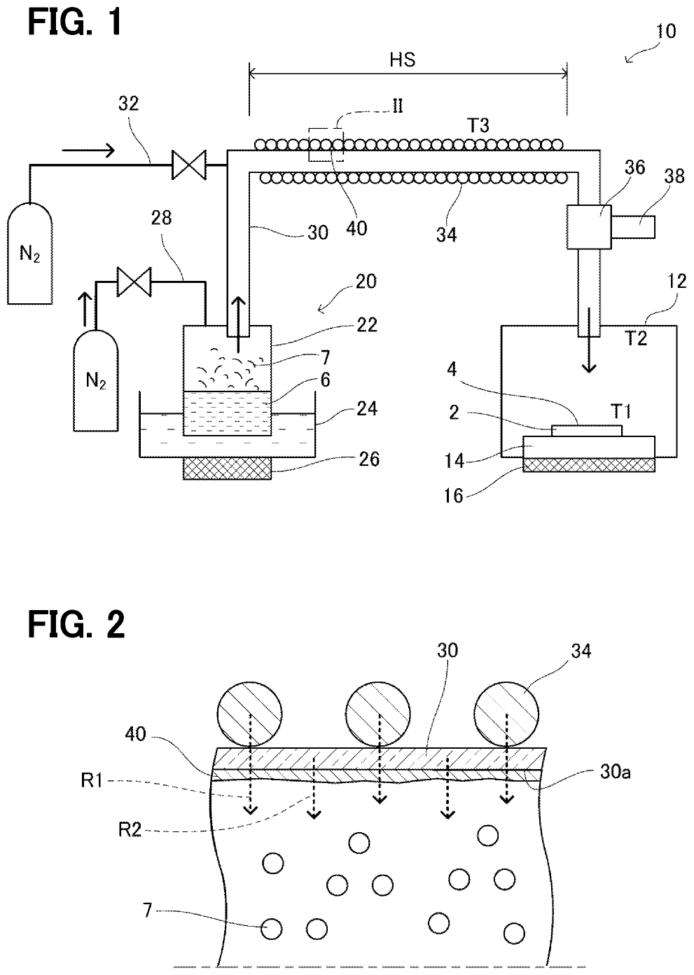

A film formation apparatus 10 according to a first embodiment of the present disclosure will be described with reference to the drawings. As shown in FIG. 1, the film formation apparatus 10 of the present embodiment forms a film 4 on the surface of a substrate 2 using a mist chemical vapor deposition (CVD) method. Although not particularly limited, the substrate 2 may be a gallium oxide substrate, and the film 4 may be a homoepitaxially grown film of gallium oxide.

The film formation apparatus 10 includes a film formation chamber 12 in which the substrate 2 is arranged, a mist generation source 20 that generates mist 7, and a mist supply path 30 that connects the mist generation source 20 and the film formation chamber 12 to each other. The film formation chamber 12 has a stage 14 on which the substrate 2 is placed and a stage heater 16 that heats the substrate 2 on the stage 14. The temperature of the substrate 2 and the temperature of the inner surface of the film formation chamber 12 facing the surface of the substrate 2 when the film 4 is formed are respectively referred to as T1 and T2. The temperature T1 of the substrate 2 and the temperature T2 of the inner surface of the film formation chamber 12 satisfy a relationship of T1>T2. Note that a specific configuration of the film formation chamber 12 is not particularly limited.

The mist generation source 20 has a raw material solution tank 22, a water tank 24 and an ultrasonic oscillator 26. The raw material solution tank 22 is a container for storing a raw material solution 6. The raw material solution 6 is a solution in which a material for forming the film 4 is dissolved and contains at least water. The raw material solution tank 22 is connected to the film formation chamber 12 via the mist supply path 30. The water tank 24 is a container for storing water. The upper part of the water tank 24 is open, and the raw material solution tank 22 is inserted into the water tank 24 from the opened upper part. The bottom surface of the raw material solution tank 22 is immersed in the water in the water tank 24.

The ultrasonic vibrator 26 is a device that generates ultrasonic waves. The ultrasonic vibrator 26 is arranged at the bottom of the water tank 24 and faces the bottom surface of the raw material solution tank 22. The ultrasonic waves generated by the ultrasonic vibrator 26 is transmitted to the raw material solution 6 in the raw material solution tank 22 through the water in the water tank 24. When the ultrasonic waves are transmitted to the raw material solution 6, the surface of the raw material solution 6 vibrates, so that the mist 7 of the raw material solution 6 is generated in the raw material solution tank 22. Although not particularly limited, the bottom surface of the raw material solution tank 22 is, for example, provided by a membrane made of a flexible material, which facilitates transmission of ultrasonic vibrations to the raw material solution 6.

A carrier gas supply path 28 is connected to the raw material solution tank 22. The carrier gas supply path 28 supplies a carrier gas such as nitrogen gas (N₂) into the raw material solution tank 22. Thus, the mist 7 generated in the raw material solution tank 22 flows into the mist supply path 30 by the flow of nitrogen gas (N₂) and is supplied into the film formation chamber 12 through the mist supply path 30. A dilution gas supply path 32 is connected to the mist supply path 30. The dilution gas supply path 32 supplies a diluent gas such as nitrogen gas (N₂) into the mist supply path 30. The mist 7 is supplied into the film formation chamber 12 at an appropriate density and flow rate by these carrier gas and diluent gas.

The mist supply path 30 is a tubular member that communicates between the raw material solution tank 22 and the film formation chamber 12. Although not particularly limited, the mist supply path 30 of the present embodiment is made of quartz. The quartz may be anhydrous quartz containing substantially no hydroxyl groups (OH groups) or quartz containing a relatively large amount of hydroxyl groups. The mist supply path 30 is provided with a heater 34. The heater 34 is arranged along the mist supply path 30 and heats at least a section HS, which is a part of the mist supply path 30. A specific configuration of the heater 34 is not particularly limited. The heater 34 heats the mist supply path 30 in order to suppress condensation and aggregation of the mist 7 passing through the mist supply path 30. The temperature of the heater 34 is referred to as T3. The temperature T3 may be 100 degrees Celsius (° C.) or higher (i.e., T3≥100), for example.

As shown in FIG. 2, infrared rays R1 generated by the heater 34 partly pass through the wall of the mist supply path 30 and are applied to the mist 7. The wavelength λ of the infrared rays R1 changes according to the temperature T3 of the heater 34 (refer to Planck's law). For example, when the temperature T3 is 400° C. (i.e., T3=400), the wavelength of the infrared rays R1 is about 2.5 to 15.2 micrometers (i.e., λ=2.5 to 15.2) and has a peak in amplitude at 5.1 micrometers (i.e., λ=5.1). Further, the mist supply path 30 heated by the heater 34 also causes infrared rays R2, and the infrared rays R2 are also applied to the mist 7. In this way, in the section HS of the mist supply path 30 heated by the heater 34, the infrared rays R1 and R2 are radiated from the inner surface 30a of the mist supply path 30 toward the mist 7, so that the mist 7 passing through the section HS of the mist supply path 30 is also heated. Therefore, the section HS heated by the heater 34 is hereinafter referred to as a mist heating section HS.

When the film formation apparatus 10 is repeatedly used, deposits resulting from condensation and aggregation of the mist 7 adhere to the inner surface 30a of the mist supply path 30. The deposits adhering to the inner surface 30a absorb the infrared rays R1 and R2 that are radiated to the mist 7 from the inner surface 30a of the mist supply path 30. Therefore, as the adhesion of the deposits progresses, the amount of heat (i.e., the dose of the infrared rays R1 and R2) transmitted to the mist 7 decreases, and the temperature rise generated in the mist 7 also decreases. As a result, the temperature of the mist 7 supplied to the substrate 2 is lowered unintentionally, thereby deteriorating the film quality. In other words, in the course of repeated use of the film formation apparatus 10, if the decrease in the amount of heat (the dose of the infrared rays R1 and R2) transmitted from the inner surface 30a of the mist supply path 30 to the mist 7 is suppressed, the deterioration of the film quality can be suppressed. For that purpose, it is conceivable to previously coat the inner surface 30a of the mist supply path 30 with a material that is equivalent to or similar to the deposits derived from the mist 7.

Based on the above findings, the inner surface 30a of the mist supply path 30 is coated with a coating layer 40 in the mist heating section HS in the present embodiment. The material forming the coating layer 40 contains at least one of oxide and hydroxide of an element present in the mist 7. Since the mist supply path 30 is made of transparent quartz and the coating layer 40 is formed on the inner surface 30a of the mist supply path 30, the mist supply path 30 has an appearance similar to frosted glass. Since the coating layer 40 is formed in advance on the inner surface 30a of the mist supply path 30, that is, the inner surface 30a of the mist supply path 30 has the coating layer 40 as a pre-coating layer, even if the deposits derived from the mist 7 further adhere, the amount of heat (the dose of infrared rays R1 and R2) transmitted from the inner surface 30a of the mist supply path 30 to the mist 7 decreases. As a result, the temperature drop of the mist 7 supplied to the substrate 2 is also suppressed, and the film formation under predetermined optimum conditions can be continued over a long period of time.

A specific configuration of the coating layer 40, such as indices such as thickness and density, is not particularly limited. However, the coating layer 40 may have an absorptivity of 50% or more with respect to the infrared rays R1 and R2 radiated from the inner surface 30a of the mist supply path 30 toward the mist 7. According to such a configuration, even when the deposits derived from the mist 7 further adhere in the course of repeated use of the film formation apparatus 10, the magnitude of decrease in the amount of infrared rays radiated to the mist 7 is effectively suppressed.

In the film formation apparatus 10 of the present embodiment, the temperature T3 of the heater 34 may be 100 degrees Celsius (° C.) or higher (i.e., T3≥100). In this case, the temperature T2 of the inner surface of the film formation chamber 12 and the temperature T3 of the heater 34 may satisfy the relationship of T2<T3. According to such a configuration, the mist 7 is mainly heated in the mist heating section HS, and is not heated so much inside the film formation chamber 12. Therefore, the temperature rise of the mist 7 in the mist heating section HS largely affects the final temperature of the mist 7 supplied to the substrate 2, and can also largely affect the film quality. For this reason, when the relationship of T2<T3 is satisfied, the film quality can be effectively stabilized by stabilizing the temperature rise of the mist 7 in the mist heating section HS. As such, the inner surface 30a of the mist supply path 30 is preferably coated with the coating layer 40 in advance, as the present embodiment described herein.

When the temperature T3 of the heater 34 is 100 degrees Celsius (° C.) or higher (i.e., T3≥100), a large amount of the infrared rays R1, R2 having the wavelength of 7.8 micrometer or less are radiated from the heater 34 based on Wien's displacement law. The wavelength of 7.8 micrometers or less is in a wavelength band that is easily absorbed by water, and largely affects the temperature rise of the mist 7 containing water. Therefore, in order to stabilize the film quality, it is particularly effective to suppress changes in the amount of infrared rays radiated to the mist 7. For this reason, the inner surface 30a of the mist supply path 30 is preferably coated with the coating layer 40 in advance.

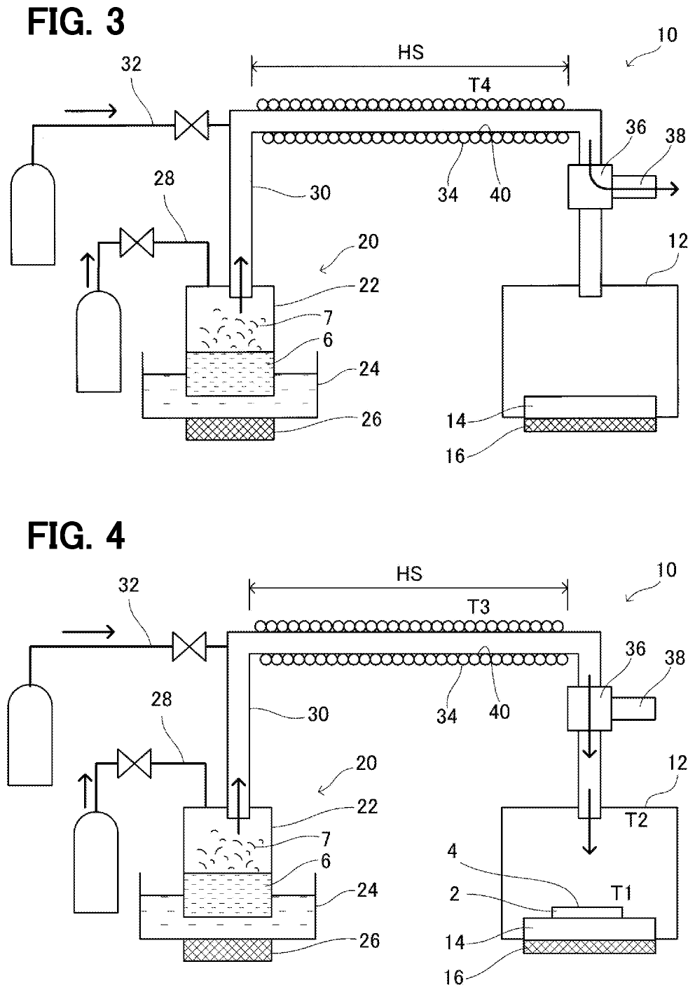

Next, a method of using the film formation apparatus 10 will be described with reference to FIGS. 3 and 4. This method of use includes a preliminary process and a film forming process performed after the preliminary process. The method of use may also be regarded as a method of producing a film on a substrate using the film formation apparatus 10 described above. As shown in FIG. 3, in the preliminary process, the mist 7 generated in the mist generation source 20 is supplied to the mist supply path 30 while the heater 34 is being operated. As a result, the coating layer 40 is formed on the inner surface 30a of the mist supply path 30, particularly on the inner surface 30a of the mist supply path 30 in the mist heating section HS. Note that the inner surface 30a of the mist supply path 30 may be formed with the coating layer 40 or may not be formed with the coating layer 40 in advance at a stage before the preliminary process is performed. In other words, the coating layer 40 may be formed by a preliminary process for the first time. In this case, the coating layer 40 can be composed only of an element contained in the mist 7.

In the preliminary process, the mist 7 in the mist supply path 30 is preferably exhausted to the outside without being supplied to the film formation chamber 12. Therefore, the mist supply path 30 may be provided with an exhaust path 38 via the branch valve 36. The branch valve 36 is positioned downstream of the mist heating section HS and configured to selectively guide the mist 7 that has passed through the mist heating section HS to either the film formation chamber 12 or the exhaust path 38.

Thereafter, in the film forming process, as shown in FIG. 4, the mist 7 generated in the mist generation source 20 is supplied to the film formation chamber 12 through the mist supply path 30 while the heater 34 is being operated. In the film formation chamber 12, the substrate 2 is arranged on the stage 14. The substrate 2 on the stage 14 is heated at a temperature T1 by the stage heater 16. In the film formation chamber 12, the mist 7 is supplied to the substrate 2 on the stage 14, so that the film 4 is formed on the surface of the substrate 2. Since the coating layer 40 is formed in advance on the inner surface 30a of the mist supply path 30, in the film forming process, the film 4 can be formed with the stable film quality.

Although not particularly limited, the temperature T4 of the heater 34 in the preliminary process and the temperature T1 of the substrate 2 in the film forming process may satisfy a relationship of T1<T4. According to such a configuration, in the preliminary process, the temperature of the inner surface 30a of the mist heating section HS is relatively high, so that the formation of the coating layer 40 is effectively promoted. In the preliminary process, the temperature of the inner surface 30a of the mist heating section HS is substantially equal to the temperature T4 of the heater 34. Further, it is preferable that the temperature T4 of the heater 34 in the preliminary process and the temperature T3 of the heater 34 in the film forming process satisfy the relationship of T3<T4. Also in this case, the temperature of the inner surface 30a of the mist heating section HS is relatively high in the preliminary process. Therefore, the formation of the coating layer 40 is effectively promoted.

Although not particularly limited, the mist 7 in the preliminary process may be the same as the mist 7 in the film forming process. In this case, although not particularly limited, the preliminary process and the film forming process may be performed continuously. However, as another embodiment, the mist 7 in the preliminary process may be different from the mist 7 in the film forming process. That is, the raw material solution 6 may be different between the preliminary process and the film forming process.

### Second Embodiment

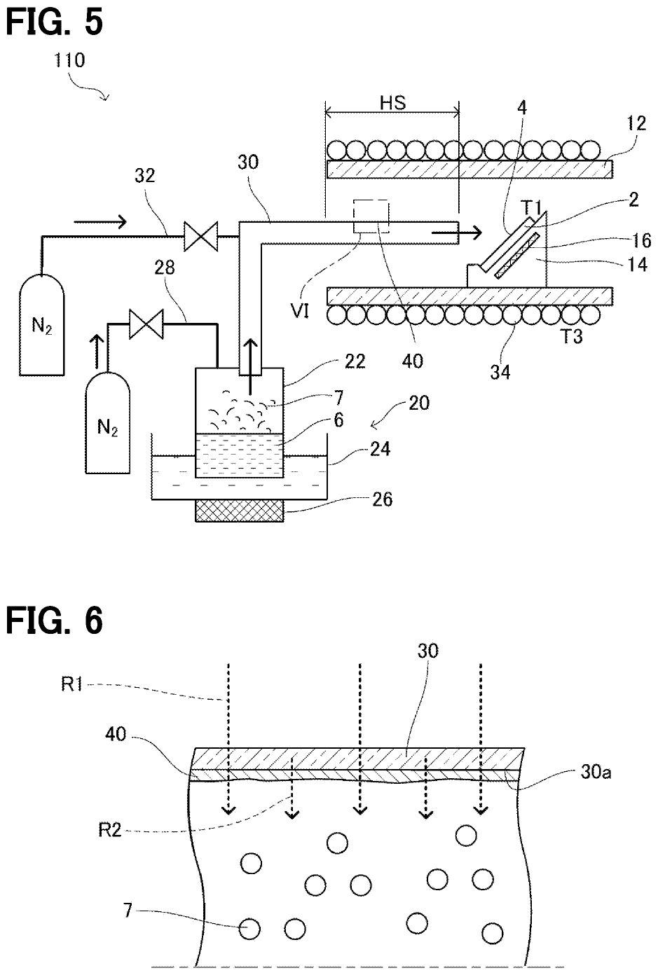

A film formation apparatus 110 of a second embodiment will be described with reference to the drawings. As shown in FIG. 5, the film formation apparatus 110 of the present embodiment forms the film 4 on the surface of the substrate 2 using a mist CVD method. The film formation apparatus 110 of the second embodiment has a basic configuration in common with the film formation apparatus 10 of the first embodiment. In the following description, the configurations common to those of the first embodiment are denoted by the same reference numerals, and description thereof will not be repeated.

In the film formation apparatus 110 of the present embodiment, the film formation chamber 12 has a cylindrical shape, and the heater 34 is provided around the film formation chamber 12. The section HS of the mist supply path 30 is located inside the film formation chamber 12 and surrounded by the heater 34. As such, the heater 34 can heat the substrate 2 on the stage 14 as well as heat the mist supply path 30. As shown in FIG. 6, the infrared rays R1 generated by the heater 34 partly passes through the mist supply path 30 and are applied to the mist 7. In addition, the mist supply path 30 heated by the heater 34 also generates infrared rays R2, and the infrared rays R2 are partly applied to the mist 7. In this way, in the section HS of the mist supply path 30 heated by the heater 34, the infrared rays R1 and R2 are radiated from the inner surface 30a of the mist supply path 30 toward the mist 7, so that the mist 7 passing therethrough is also heated. Therefore, also in this case, the section HS of the mist supply path 30 heated by the heater 34 is also referred to as the mist heating section HS.

Also in the present embodiment, the inner surface 30a of the mist supply path 30 in the mist heating section HS is coated with the coating layer 40. The material forming the coating layer 40 contains at least one of oxide and hydroxide of an element present in the mist 7. Since the coating layer 40 is formed in advance on the inner surface 30a of the mist supply path 30, even if the deposits derived from the mist 7 further adhere, the magnitude of decrease in the amount of heat (the dose of the infrared rays R1 and R2) transmitted from the inner surface 30a of the mist supply path 30 to the mist 7 is reduced. As a result, the temperature drop of the mist 7 supplied to the substrate 2 is also suppressed, and the film formation under predetermined optimum conditions can be continued over a long period of time.

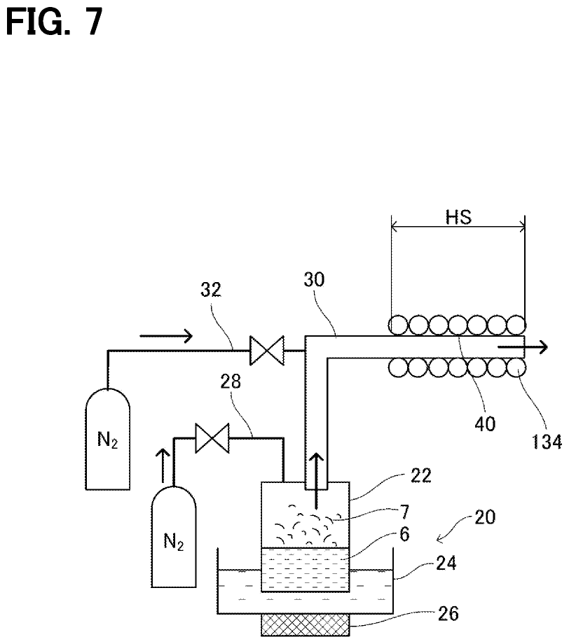

Next, a method of using the film formation apparatus 110 will be described with further reference to FIG. 7. The method of use includes a preliminary process and a film forming process performed after the preliminary process. As shown in FIG. 7, the preliminary process can be performed in a state where the mist generation source 20 and the mist supply path 30 are removed from the film formation chamber 12. In this case, a preliminary heater 134 for the preliminary process may be attached to the mist heating section HS. In the preliminary process, the mist 7 generated in the mist generation source 20 is supplied to the mist supply path 30 while the heater 134 is being operated. As a result, the coating layer 40 is formed on the inner surface 30a of the mist supply path 30, particularly on the inner surface 30a located in the mist heating section HS (see FIG. 6).

Thereafter, in the film forming process, the mist generation source 20 and the mist supply path 30 are attached to the film formation chamber 12, as shown in FIG. 5. Then, while operating the heater 34, the mist 7 generated by the mist generation source 20 is supplied to the film formation chamber 12 through the mist supply path 30. In the film formation chamber 12, the substrate 2 is arranged on the stage 14. The mist 7 supplied to the substrate 2 on the stage 14 forms the film 4 on the surface of the substrate 2. Also in the present embodiment, since the coating layer 40 is formed in advance on the inner surface 30a of the mist supply path 30, the film can be formed with the stable film quality in the film forming process.

### Third Embodiment

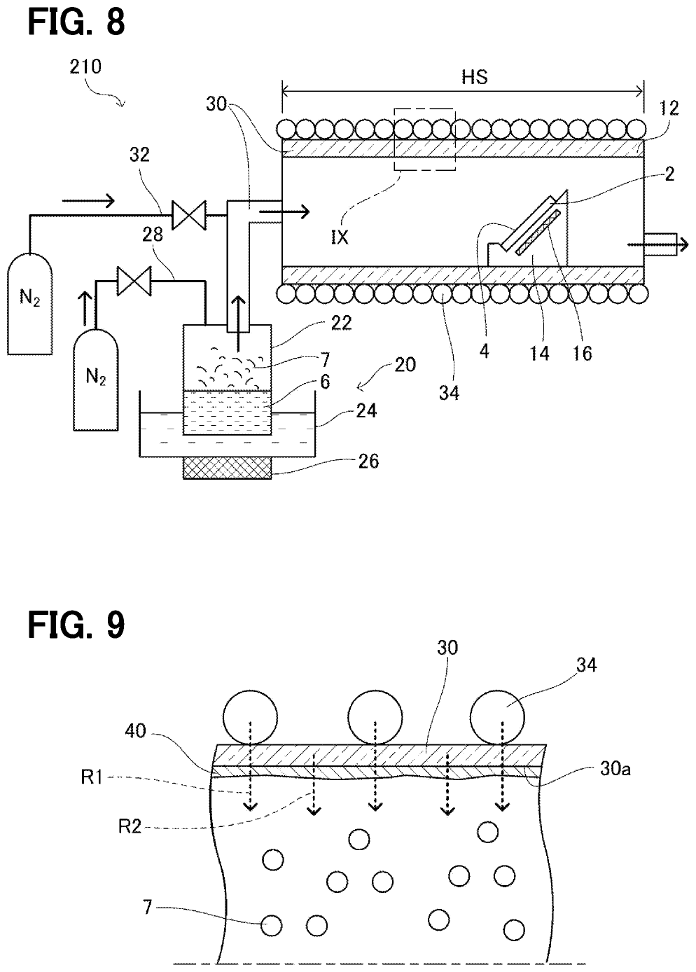

A film formation apparatus 210 of the third embodiment will be described with reference to the drawings. As shown in FIG. 8, the film formation apparatus 210 of the present embodiment forms the film 4 on the surface of the substrate 2 using the mist CVD method. The film formation apparatus 210 of the third embodiment has a basic configuration in common to the film formation apparatus 10 of the first embodiment. In the following description, the configurations common to those of the first embodiment are denoted by the same reference numerals, and description thereof will not be repeated.

In the film formation apparatus 210 of the present embodiment, a part of the mist supply path 30 and the film formation chamber 12 are provided by a common cylindrical member, and the heater 34 is disposed around the cylindrical member. That is, the part of the mist supply path 30 and the film formation chamber 12 share the cylindrical member. Therefore, in the film formation apparatus 210 of the present embodiment, the boundary between the mist supply path 30 and the film formation chamber 12 is not particularly defined, and it can be interpreted that the mist supply path 30 includes the film formation chamber 12. As shown in FIG. 9, the infrared rays R1 generated by the heater 34 partly pass through the mist supply path 30 and are radiated to the mist 7. In addition, the mist supply path 30 heated by the heater 34 also generates infrared rays R2, and the infrared rays R2 are partly radiated to the mist 7. In this way, in the section HS of the mist supply path 30 heated by the heater 34, the infrared rays R1 and R2 are radiated from the inner surface 30a of the mist supply path 30 toward the mist 7, so that the mist 7 passing through the section HS is also heated. Therefore, also in this case, the section HS heated by the heater 34 is also referred to as the mist heating section HS. The heater 34 in the present embodiment also functions as a heater for heating the substrate 2 on the stage 14.

Also in the present embodiment, the inner surface 30a of the mist supply path 30 in the mist heating section HS is coated with the coating layer 40. The material forming the coating layer 40 contains at least one of oxide and hydroxide of an element present in the mist 7. Since the coating layer 40 is formed in advance on the inner surface 30a of the mist supply path 30, even if the deposits derived from the mist 7 further adhere, the magnitude of decrease in the amount of heat (the dose of the infrared rays R1 and R2) transmitted from the inner surface 30a of the mist supply path 30 to the mist 7 is reduced. As a result, the temperature drop of the mist 7 supplied to the substrate 2 is also suppressed, and the film formation under predetermined optimum conditions can be continued over a long period of time.

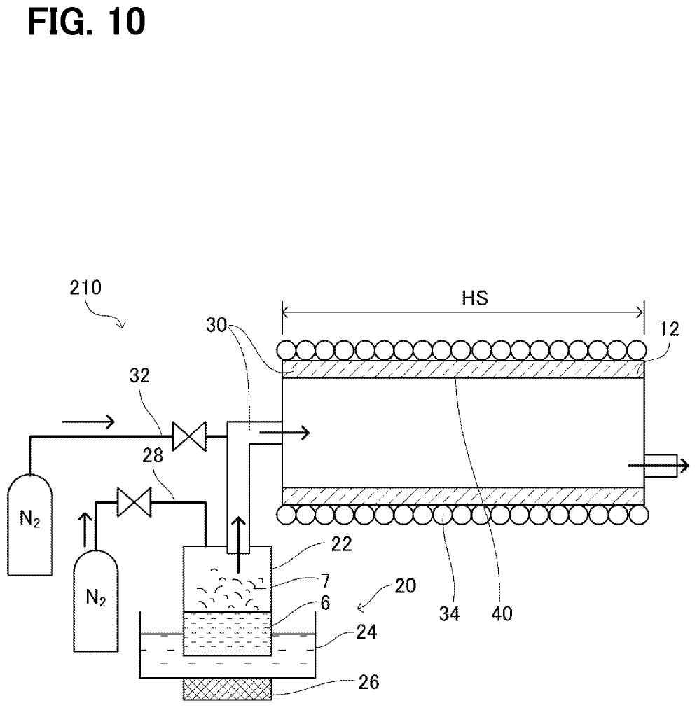

Next, a method of using the film formation apparatus 210 will be described with further reference to FIG. 10. The method of use has a preliminary process and a film forming process performed after the preliminary process. As shown in FIG. 10, the preliminary process can be performed in a state where the stage 14 is removed from the film formation chamber 12. In the preliminary process, the mist 7 generated by the mist generation source 20 is supplied to the mist supply path 30 while the heater 34 is being operated. As a result, the coating layer 40 is formed on the inner surface 30a of the mist supply path 30, particularly on the inner surface 30a of the mist supply path 30 in the mist heating section HS (see FIG. 9).

Thereafter, as shown in FIG. 8, in the film forming process, the stage 14 on which the substrate 2 is mounted is placed in the film formation chamber 12. Then, while operating the heater 34, the mist 7 generated by the mist generation source 20 is supplied to the film formation chamber 12 through the mist supply path 30. In the film formation chamber 12, the mist 7 supplied to the substrate 2 on the stage 14 forms a film 4 on the surface of the substrate 2. Also in the present embodiment, since the coating layer 40 is formed in advance on the inner surface 30a of the mist supply path 30, the film 4 can be formed with stable film quality in the film forming process.

### Fourth Embodiment

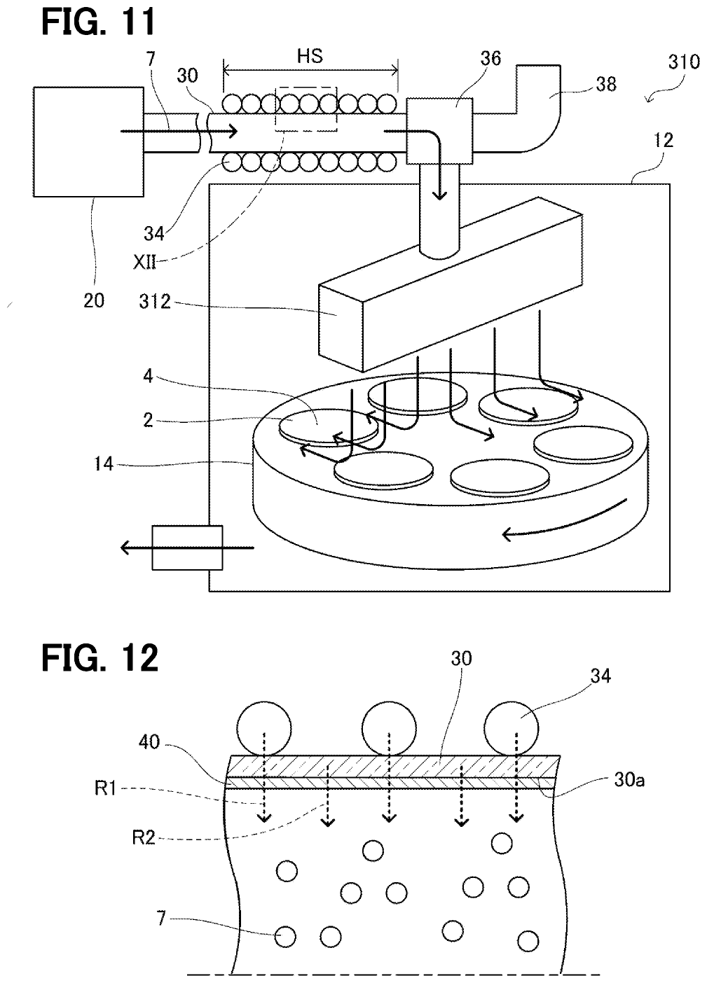

A film formation apparatus 310 of the fourth embodiment will be described with reference to the drawings. As shown in FIG. 11, the film formation apparatus 310 of the present embodiment forms the film 4 on the surface of the substrate 2 using a mist CVD method. The film formation apparatus 310 of the fourth embodiment has a basic configuration in common with the firm formation apparatus 10 of the first embodiment. In the following description, configurations common to those of the first embodiment are denoted by the same reference numerals, and descriptions thereof will not be repeated.

In the film formation apparatus 310 of the present embodiment, the stage 14 is a turntable, and a plurality of substrates 2 can be placed on the stage 14. Further, the film formation chamber 12 is provided with a duct 312 connected to the mist supply path 30, so that the mist 7 from the mist supply path 30 is supplied to the substrates 2 on the stage 14 through the duct 312. The mist supply path 30 is provided with an exhaust path 38 via a branch valve 36 as in the first embodiment.

A heater 34 is provided in a section HS of the mist supply path 30. As shown in FIG. 12, the infrared rays R1 generated by the heater 34 partly pass through the mist supply path 30 and are radiated to the mist 7. In addition, the mist supply path 30 heated by the heater 34 also generates infrared rays R2, and he infrared rays R2 are partly radiated to the mist 7. In this way, in the section HS of the mist supply path 30 heated by the heater 34, the infrared rays R1 and R2 are radiated from the inner surface 30a of the mist supply path 30 toward the mist 7, so that the mist 7 passing through the section HS is also heated. Therefore, also in this case, the section HS heated by the heater 34 is also referred to as the mist heating section HS.

Also in this embodiment, the inner surface 30a of the mist supply path 30 in the mist heating section HS is coated with the coating layer 40. The material forming the coating layer 40 contains at least one of oxide and hydroxide of an element present in the mist 7. Since the coating layer 40 is formed in advance on the inner surface 30a of the mist supply path 30, even if the deposits derived from the mist 7 further adhere, the magnitude of decrease in the amount of heat (the dose of the infrared rays R1 and R2) transmitted from the inner surface 30a of the mist supply path 30 to the mist 7 is reduced. As a result, the temperature drop of the mist 7 supplied to the substrates 2 is also suppressed, and the film formation under predetermined optimum conditions can be continued over a long period of time.

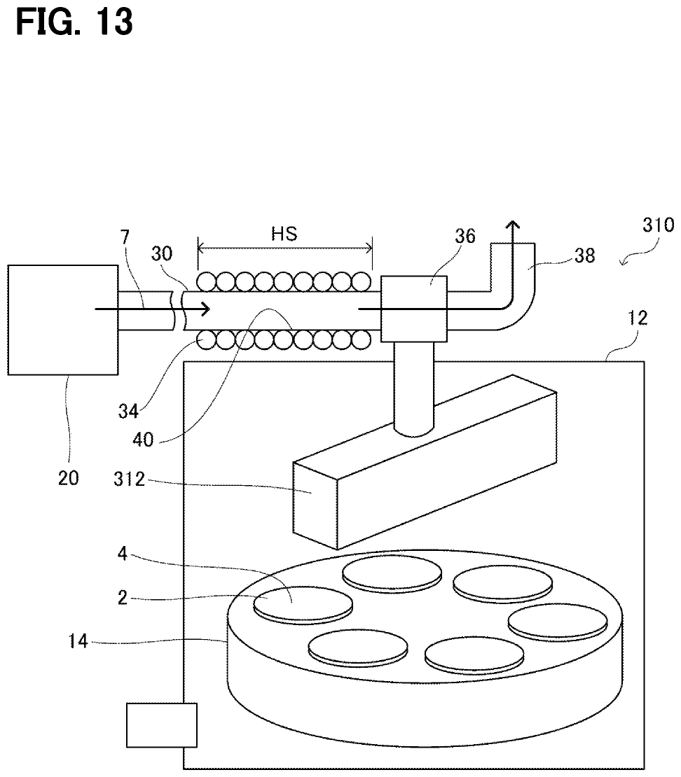

Next, a method of using the film formation apparatus 310 will be described with further reference to FIG. 13. The method of use includes a preliminary process and a film forming process performed after the preliminary process. As shown in FIG. 13, in the preliminary process, the mist 7 generated by the mist generation source 20 is supplied to the mist supply path 30 while the heater 34 is being operated. As a result, the coating layer 40 is formed on the inner surface 30a of the mist supply path 30, particularly on the inner surface 30a of the mist supply path 30 in the mist heating section HS (see FIG. 12). The mist 7 that has passed through the mist heating section HS may be discharged to the outside through the exhaust path 38.

Thereafter, in the film forming process, the mist generation source 20 and the mist supply path 30 are attached to the film formation chamber 12, as shown in FIG. 11. Then, while operating the heater 34, the mist 7 generated by the mist generation source 20 is supplied to the film formation chamber 12 through the mist supply path 30. In the film formation chamber 12, the substrate 2 is placed on the stage 14, and the mist 7 supplied to the substrate 2 on the stage 14 forms a film 4 on the surface of the substrate 2. Also in the present embodiment, since the coating layer 40 is formed in advance on the inner surface 30a of the mist supply path 30, the film 4 can be formed with stable film quality in the film forming process.

Although the embodiments of the present disclosure have been described in detail hereinabove, these are merely examples and do not limit the scope of the present disclosure. The techniques described in the present disclosure include various modifications of the embodiments described hereinabove. The technical elements described in the present disclosure or the drawings exhibit technical usefulness alone or in various combinations, and are not limited to the combinations described in the present disclosure at the time of filing. The techniques illustrated in the present disclosure or drawings can achieve multiple objectives at the same time, and achieving one of the objectives itself has technical usefulness.

What is claimed is:

1. A film formation apparatus for forming a film on a surface of a substrate, the film formation apparatus comprising:
a stage on which the substrate is to be placed;
a mist generation source configured to generate a mist of a solution containing at least water and in which a material for forming the film is dissolved;
a supply path configured to convey the mist generated by the mist generation source toward the substrate on the stage by a flow of a carrier gas; and
a heater configured to heat at least a part of the supply path, wherein
the part of the supply path heated by the heater is provided as a mist heating section in which infrared rays are radiated from an inner surface of the supply path toward the mist, and
the inner surface of the supply path in the mist heating section is coated with a coating layer containing at least one of an oxide and a hydroxide of an element present in the mist.

2. The film formation apparatus according to claim 1, wherein
the coating layer is made of only the element contained in the mist.

3. The film formation apparatus according to claim 1, wherein
the supply path includes a film formation chamber in which the stage is disposed,
a temperature of the substrate when the film is formed is referred to as T1,
a temperature of an inner surface of the film formation chamber facing the surface of the substrate is referred to as T2, and
the temperature T1 and the temperature T2 satisfy a relationship of T1>T2.

4. The film formation apparatus according to claim 1, wherein
the coating layer in the mist heating section has an absorptivity of 50% or more of the infrared rays radiated toward the mist from the inner surface of the supply path.

5. The film formation apparatus according to claim 1, wherein
the film formed on the surface of the substrate is an epitaxial film.

6. The film formation apparatus according to claim 1, wherein
the inner surface of the supply path in the mist heating section is made of quartz.

7. The film formation apparatus according to claim 6, wherein
the quartz contains a hydroxyl group.

8. The film formation apparatus according to claim 1, wherein
a temperature of the heater is referred to as T3, and the temperature T3 is 100 degrees Celsius or higher.

9. The film formation apparatus according to claim 1, wherein
the supply path includes a film formation chamber in which the stage is disposed, and
a temperature of an inner surface of the film formation chamber is referred to as T2,
a temperature of the heater is referred to as T3, and
the temperature T2 and the temperature T3 satisfy a relationship of T2<T3.

10. The film formation apparatus according to claim 1, wherein
the infrared rays radiated toward the mist have a wavelength of 7.8 micrometers or less.

11. A method of using a film formation apparatus that forms a film on a surface of a substrate, the film formation apparatus including:
a stage on which the substrate is to be placed;
a mist generation source configured to generate a mist of solution that contains at least water and in which a material for forming the film is dissolved;
a supply path configured to convey the mist generated by the mist generation source toward the substrate on the stage by a flow of a carrier gas; and
a heater configured to heat at least at part of a supply path as a mist heating section in which infrared rays are radiated toward the mist from an inner surface of the supply path,
the method comprising:
forming a coating layer on the inner surface of the supply path in the mist heating section by supplying the mist generated by the mist generation source to the mist heating section while operating the heater; and
after the forming of the coating layer, forming the film on the surface of the substrate by supplying the mist generated by the mist generation source to the substrate on the stage through the supply path while operating the heater.

12. The method according to claim 11, wherein
a temperature of the inner surface of the mist heating section in the forming of the coating layer is referred to as T4,
a temperature of the heater in the forming of the film is referred to as T3, and
the temperature T3 and the temperature T4 satisfy a relationship of T3<T4.

13. The method according to claim 11, wherein
a temperature of the inner surface of the supply path in the mist heating section in the forming of the coating layer is referred to as T4,
a temperature of the substrate in the forming of the film is referred to as T1, and
the temperature T4 and the temperature T1 satisfy a relationship of T1<T4.

14. The method according to claim 11, wherein
the mist generated in the forming of the coating layer is a same as the mist generated in the forming of the film.

15. The method according to claim 11, wherein
the forming of the film is performed continuously after the forming of the coating layer.
